(19) United States
(12) Patent Application Publication
(10) Pub. No.: US 2009/0176381 A1
(43) Pub. Date: Jul. 9, 2009

(54) METHOD OF MANUFACTURING SEMICONDUCTOR DEVICE AND SUBSTRATE PROCESSING APPARATUS

(75) Inventors: Shin HIYAMA, Toyama-shi (JP); Toru Kakuda, Toyama-shi (JP); Yukitomo Hirochi, Toyama-shi (JP)

Correspondence Address: MATTINGLY & MALUR, P.C., 1800 DIAGONAL ROAD, SUITE 370, ALEXANDRIA, VA, 22314, US

(73) Assignee: Hitachi-Kokusai Electric Inc.

(21) Appl. No.: 12/344,899

(22) Filed: Dec. 29, 2008

(30) Foreign Application Priority Data
Jan. 8, 2008 (JP) 2008-000956

(51) Int. Cl. H01L 21/26; B01J 19/08

(52) U.S. Cl. 438/795; 422/186.05; 257/E21.328

(57) ABSTRACT

There are provided a method of manufacturing a semiconductor device and a substrate processing apparatus that are designed to suppress a popping phenomenon and reduce residues remaining on a substrate in a photoresist removing process. Oxygen gas and hydrogen gas are supplied to a plasma generating chamber while maintaining the hydrogen atom/oxygen atom ratio of the oxygen and hydrogen gases equal to or higher than 3, and the oxygen gas and the hydrogen gas are excited into plasma in the plasma generating chamber so as to remove photoresist from a substrate accommodated in a treatment chamber installed contiguous to the plasma generating chamber.

### CROSS-REFERENCE TO RELATED PATENT APPLICATION

This U.S. non-provisional patent application claims priority under 35 U.S.C. § 119 of Japanese Patent Application No. 2008-000956, filed on Jan. 8, 2008, in the Japanese Patent Office, the entire contents of which are hereby incorporated by reference.

### BACKGROUND OF THE INVENTION

1. Field of the Invention

The present invention relates to a semiconductor device manufacturing method including a process of removing photoresist from a substrate, and a substrate processing apparatus.

2. Description of the Prior Art

A semiconductor device manufacturing method includes a dry-ashing process for removing photoresist (a photoresist film) used as a pattern mask. According to the well-known technology for the dry-ashing removing process, a substrate is charged into an airtight treatment chamber, and while supplying a reaction gas to a plasma active space installed in the treatment chamber (for example, installed at the upper part of the treatment chamber), high-frequency power is applied to the plasma source to generate plasma and remove photoresist from the substrate by oxidizing and vaporizing the photoresist using reactive active species (radicals) included in the plasma. In the technology, since photoresist is an organic film, oxygen (O₂) gas or an oxygen (O₂) based reaction gas is generally used (for example, refer to Patent Document 1 below).

[Patent Document 1] Published Japanese translations of PCT international publication for Patent Application Publication No. 2001-508887

However, in a conventional method of manufacturing a semiconductor device, a surface layer of photoresist applied to a substrate is hardened to a state where the surface layer is not readily stripped. If an ashing process is performed in that state, the other part of the photoresist underlying the hardened surface layer becomes flowable, and bubbles included in the photoresist are heated and expanded. Thus, the expanded bubbles may spout through the hardened surface layer, which is so called a popping phenomenon. If the popping phenomenon occurs, abnormally oxidized organic components, and oxides of dopants such as phosphorus (P), arsenic (As), and boron (B) implanted into the photoresist by an ion implantation process may not be removed through the ashing process, and thus residues may remain on the substrate.

Although the substrate is cleaned in a wet cleaning process after the ashing process, the residues may not be removed in some cases. Moreover, the residues remaining on the substrate may result in a problem such as a more frequent change of cleaning liquid in the wet cleaning process.

### SUMMARY OF THE INVENTION

An object of the present invention is to provide a method of manufacturing a semiconductor device and a substrate processing apparatus that are designed to suppress a popping phenomenon and reduce residues remaining on a substrate in a photoresist removing process.

According to an aspect of the present invention, there is provided a method of manufacturing a semiconductor device, the method comprising a process of removing photoresist from a substrate, wherein the removing process is performed by supplying a reaction gas to a reaction vessel, exciting the reaction gas using the reaction vessel, and ashing a substrate accommodated in a treatment chamber installed contiguous to the reaction vessel by using the plasma, wherein the reaction gas has a hydrogen atom/oxygen atom ratio equal to or higher than 3.

### BRIEF DESCRIPTION OF THE DRAWINGS

FIG. 1 is a schematic cross-sectional view illustrating an ashing apparatus in accordance with a preferred embodiment of the present invention.

FIG. 2 is a schematic vertical sectional view illustrating the ashing apparatus in accordance with a preferred embodiment of the present invention.

FIG. 3 is a schematic vertical sectional view illustrating the ashing apparatus in accordance with a preferred embodiment of the present invention.

FIG. 4 is a sectional view illustrating a process chamber of the ashing apparatus in accordance with a preferred embodiment of the present invention.

FIG. 5 is a graph showing emission intensity corresponding to concentrations of OH, O, and H radicals included in plasma with respect to a hydrogen/oxygen (H/O) ratio of a reaction gas composed of H₂ and O₂.

FIG. 6 is a graph showing emission intensity corresponding to concentrations of OH, O, and H radicals included in plasma with respect to a H/O ratio of a reaction gas composed of H₂O and O₂—FIG. 7 is a graph showing the amount of residues on a substrate with respect to a H/O ratio of a reaction gas after photoresist is removed from the substrate using plasma obtained by exciting the reaction gas for the case where the reaction gas is composed of H₂ and O₂ and the case where the reaction gas is composed of H₂O and H₂.

FIG. 8 is a graph showing stripping time and the amount of residues with respect to the total flow rate of a reaction gas.

FIG. 9 is a graph providing information about the amount of residues remaining after an ashing process with respect to the process pressure of the ashing process by showing the number of 1-μm or larger particles remaining on the surface of a 300-mm wafer.

### DETAILED DESCRIPTION OF THE PREFERRED EMBODIMENTS

Preferable embodiments of the present invention will be described hereinafter with reference to the attached drawings. In the preferred embodiments of the present invention, a method of manufacturing a semiconductor device is implemented by an ashing apparatus used as a semiconductor device manufacturing apparatus.

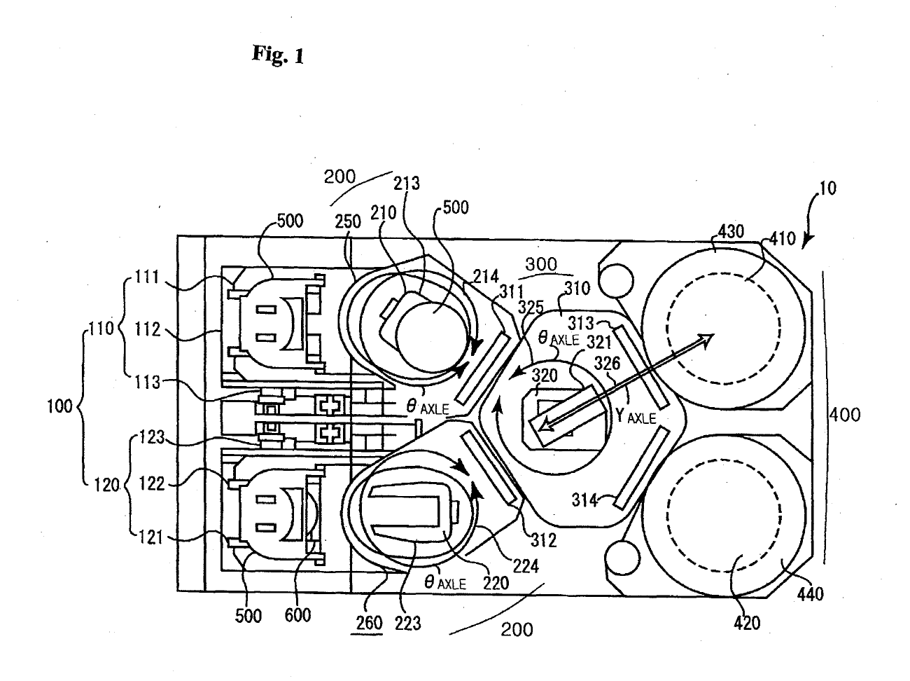

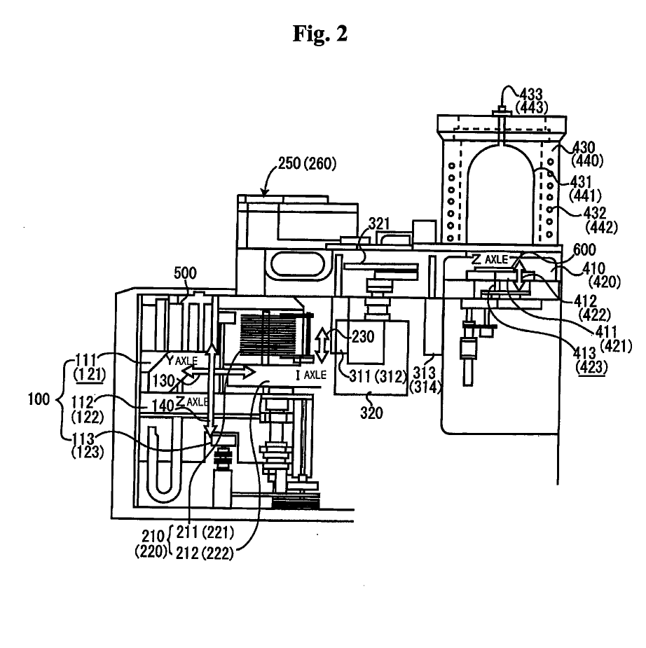

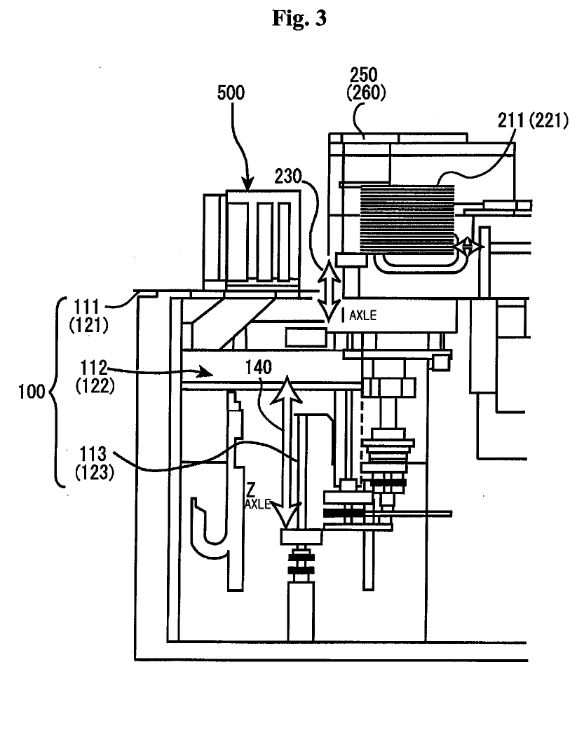

FIG. 1 is a schematic cross-sectional view illustrating an ashing apparatus in accordance with a preferred embodiment of the present invention, and FIG. 2 and FIG. 3 are schematic vertical sectional views illustrating the ashing apparatus in accordance with preferred embodiments of the present invention. As shown in FIG. 1 and FIG. 2, the ashing apparatus 10 includes a cassette transfer mechanism 100, a loadlock chamber unit 200, a transfer module unit 300, and a process chamber unit 400 used as a treatment chamber for performing an ashing process.

The cassette transfer mechanism 100 includes cassette transfer units 110 and 120 as first carrying units. The cassette transfer units 110 and 120 include: cassette tables 111 and 121 for placing cassettes 500 that are used to support wafers 600 used as substrates; Y-axle assemblies 112 and 122 for driving Y-axles 130 of the cassette tables 111 and 121; and Z-axle assemblies 113 and 123 for driving Z-axles 140 of the cassette tables 111 and 121.

The loadlock chamber unit 200 includes loadlock chambers 250 and 260, and buffer units 210 and 220 configured to receive wafers 600 from cassette tables 111 and 121 and hold the wafers 600 in the loadlock chambers 250 and 260. The buffer units 210 and 220 include buffer finger assemblies 211 and 221, and index assemblies 212 and 222 under the buffer finger assemblies 211 and 221. The buffer finger assembly 211 (221), and the index assembly 212 (222) are simultaneously rotated by a θ-axle 214 (224).

The transfer module unit 300 includes a transfer module 310 as a carrying chamber, and the loadlock chambers 250 and 260 are attached to the transfer module 310 with gate values 311 and 312 being disposed therebetween. At the transfer module 310, a vacuum arm robot unit 320 is installed as a second carrying unit.

The process chamber unit 400 includes process chambers 410 and 420 as treatment chambers, and plasma generating chambers 430 and 440 above the process chambers 410 and 420. The process chambers 410 and 420 are attached to the transfer module 310 with gate valves 313 and 314 being disposed therebetween.

The process chambers 410 and 420 include susceptor tables 411 and 421 for placing wafers 600 thereon. Lift pins 413 and 423 passed through the susceptor tables 411 and 421, respectively. The lift pins 413 and 423 move upward and downward in the directions of Z-axles 412 and 422.

The plasma generating chambers 430 and 440 include reaction vessels 431 and 441, respectively, and resonance coils 432 and 442 are installed outside the reaction vessels 431 and 441. High-frequency power is applied to the resonance coils 432 and 442 so as to excite a reaction gas, which is introduced through gas introduction ports 433 and 443 for ashing. The reaction gas becomes plasma, and the plasma removes photoresist of wafers 600 placed on the susceptor tables 411 and 421.

In the ashing apparatus 10, wafers 600 are carried from the cassette table 111 (121) to the loadlock chamber 250 (260). For this, as shown in FIG. 2 and FIG. 3, the cassette 500 is placed on the cassette table 111 (121), and the Z-axle 140 operates downwardly. In the state where the Z-axle 140 is at a lower position, the Y-axle 130 of the buffer finger assembly 211 (221) operates toward the cassette 500.

As an I-axle 230 operates, a buffer finger 213 (223) of the buffer finger assembly 211 (221) receives twenty five wafers 600 from the cassette 500. Thereafter, the Y-axle 130 returns its original position.

A wafer 600 held by the buffer unit 210 (220) in the loadlock chamber 250 (260) is loaded to a finger 321 of the vacuum arm robot unit 320. The vacuum arm robot unit 320 is rotated in the direction of a θ-axle 325, and the finger 321 is extended in the direction of a Y-axle 326, in order to transfer the wafer 600 to the susceptor table 411 (421) inside the process chamber 410 (420).

Hereinafter, an explanation will be given on the operation of transferring the wafer 600 from the finger 321 to the susceptor table 411 (421).

By a cooperative operation of the finger 321 of the vacuum arm robot unit 320 and the lift pin 413 (423), the wafer 600 is transferred onto the susceptor table 411 (421). After the wafer 600 is processed, the wafer 600 is transferred from the susceptor table 411 (421) to the buffer unit 210 (220) inside the loadlock chamber 250 (260) by the vacuum arm robot unit 320.

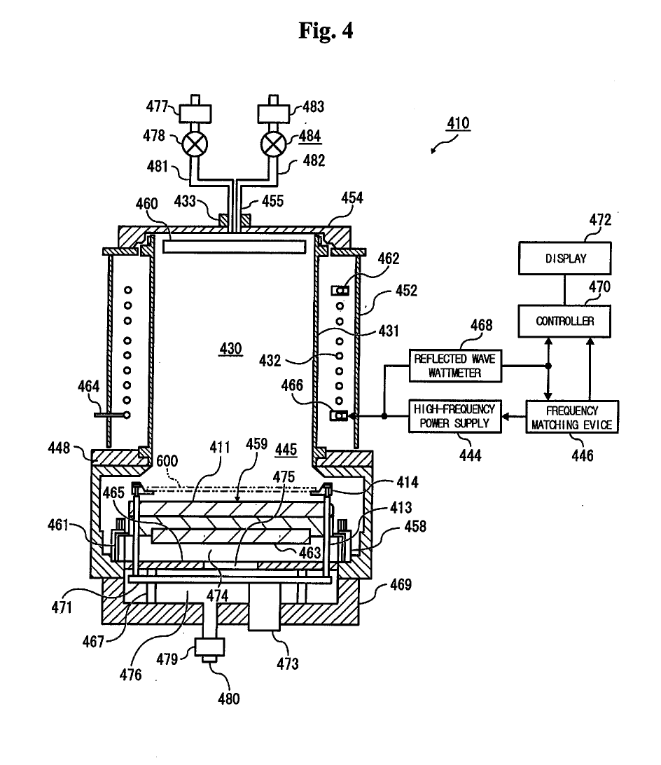

In FIG. 4, the process chamber 410 is illustrated in detail. The process chamber 420 has the same structure as the process chamber 410.

The process chamber 410 is a high-frequency electrodeless discharge type process chamber for performing an ashing process on a semiconductor substrate or device as a dry treatment process. As shown in FIG. 4, the process chamber 410 includes the plasma generating chamber 430 configured to generate plasma, a treatment chamber 445 configured to accommodate a semiconductor substrate such as a wafer 600, a high-frequency power supply 444 configured to supply high-frequency power to the plasma generating chamber 430 (particularly, to the resonance coil 432), and a frequency matching device 446 configured to control the oscillating frequency of the high-frequency power supply 444. For example, the plasma generating chamber 430 is located at the upper side of a horizontal base plate 448 used as a pedestal, and the treatment chamber 445 is located at the lower side of the horizontal base plate 448. The resonance coil 432 and an outer shield 452 constitute a spiral resonator.

The plasma generating chamber 430 is configured to be evacuated. The plasma generating chamber 430 includes the reaction vessel 431 to which a reaction gas is supplied for generating plasma, the resonance coil 432 which is wound around the reaction vessel 431, and the outer shield 452 which is disposed outside the resonance coil 432 and is electrically grounded.

The reaction vessel 431 is a chamber which is generally made of high-purity quartz glass or a ceramic material in a cylindrical shape. Generally, the centerline of the reaction vessel 431 is aligned in a vertical direction, and top and bottom ends of the reaction vessel 431 are air-tightly sealed by a top plate 454 and the treatment chamber 445. At the bottom of the treatment chamber 445 located at the lower side of the reaction vessel 431, a susceptor 459 is installed, which is supported by a plurality of supports 461 (for example, four supports) and is provided with the susceptor table 411 and a substrate heating unit 463 configured to heat a wafer disposed on the susceptor 459.

At the lower side of the susceptor 459, an exhaust plate 465 is installed. The exhaust plate 465 is supported by a lower base plate 469 with guide shafts 467 being disposed therebetween, and the lower base plate 469 is air-tightly installed to the bottom of the treatment chamber 445. A lift base plate 471 is installed using the guide shafts 467 as guides so as to be moved upward and downward. The lift base plate 471 includes at least three lift pins 413.

The lift pins 413 are inserted through the susceptor 459. At the tops of the lift pins 413, lift pin supporting parts 414 are installed for supporting a wafer 600.

The lift pin supporting parts 414 extend toward the center of the susceptor 459. By moving the lift pins 413 downward or upward, a wafer 600 can be placed onto the susceptor table 411 or lifted from the susceptor table 411.

A lift shaft 473 of a lift driving unit (not shown) is connected to the lift base plate 471 through the lower base plate 469. The lift driving unit moves the lift shaft 473 upward or downward so that the lift pin supporting parts 414 connected to the lift shaft 473 through the lift base plate 471 and the lift pins 413 can be moved upward and downward.

Between the susceptor 459 and the exhaust plate 465, a cylindrical baffle ring 458 is installed. A first exhaust chamber 474 is formed by the baffle ring 458, the susceptor 459, and the exhaust plate 465. In the side part of the cylindrical baffle ring 458, a plurality of air holes are uniformly formed. Therefore, the first exhaust chamber 474 can be separated from the treatment chamber 445 and communicate with the treatment chamber 445 through the air holes.

At the center of the exhaust plate 465, an exhaust hole 475 is formed. The first exhaust chamber 474 communicates with a second exhaust chamber 476 through the exhaust hole 475. An exhaust pipe 480 communicates with the second exhaust chamber 476, and an exhaust device 479 is installed at the exhaust pipe 480.

At the top plate 454 of the reaction vessel 431, gas supply pipes 455, which extend from gas supply equipment (not shown) for supplying reaction gases necessary for generating plasma and are provided with gas supply units, are connected to the gas introduction port 433. At the gas supply pipes 455, a first gas supply unit is installed for supplying O₂ gas, and a second gas supply unit is installed for supplying another gas (N₂ gas and H₂ gas in the current embodiment). At the first and second gas supply units, mass flow controllers 477 and 483 used as supply pipe flow rate control units, and on-off valves 478 and 484 are respectively installed. By controlling the mass flow controllers 477 and 483 and the on-off valves 478 and 484, the amount of gas supply can be controlled.

Although one gas supply pipe is used for supplying H₂ gas and N₂ gas in the current embodiment, the present invention is not limited thereto. Gas supply pipes each having a mass flow controller and an on-off value can be used for supplying H₂ gas and N₂ gas. However, it is preferable that N₂ gas and H₂ gas be previously mixed at a gas supply source (not shown) because the N₂ gas is used to dilute the H₂ gas.

In the reaction vessel 431, a baffle plate 460 having a disk shape and made of quartz is installed to guide a flow of a reaction gas along the inner wall of the reaction vessel 431.

By controlling gas supply and exhaust through the flow rate control units and the exhaust device 479, the pressure inside the treatment chamber 445 can be adjusted.

The winding diameter, winding pitch, and number of turns of the resonance coil 432 are adjusted to resonate the resonance coil 432 in constant wavelength mode so that standing waves having a predetermined wave length can be generated from the resonance coil 432. That is, the electric length of the resonance coil 432 is set to a length corresponds to a length that is an integer number (1, 2, . . . ) of times, ½, or ¼ the wavelength of power supplied from the high-frequency power supply 444.

For example, if the frequency of power is 13.56 MHz, the wavelength of the power is about 22 meters; if the frequency is 27.12 MHz, the wavelength is about 11 meters; and if the frequency is 54.24 MHz, the wavelength is about 5.5 meters.

If the electric length of the resonance coil 432 is set to a length corresponding to one wavelength, the height of the plasma generating chamber 430 is relatively large. In this case, a relatively long time is given for exciting a process gas into a plasma state so that the process gas can be surely excited into the plasma state. On the other hand, if the electric length of the resonance coil 432 is set to a length corresponding to ½ or ¼ of the wavelength, the length of the resonance coil 432 is relatively short such that the height of the plasma generating chamber 430 is relatively small as compared with the case where the electric length of the resonance coil 432 is set to a length corresponding to one wavelength.

Specifically, the resonance coil 432 can be adjusted in consideration of power supply, the strength of a magnetic field, or the outer shape of an application apparatus. For example, to generate a magnetic field of about 0.01 gausses to about 10 gausses by using 800 KHz to 50 MHz, 0.5 KW to 5 KW high-frequency power, the resonance coil 432 may have an effective cross sectional area of 50 mm² to 300 mm² and a diameter of 200 mm to 500 mm and be wound about 2 times to about 60 times around the reaction vessel 431. The resonance coil 432 is made of a material such as copper pipe, a copper thin plate, an aluminum pipe, an aluminum thin plate, and a polymer belt on which copper or aluminum is deposited. The resonance coil 432 is supported by a plurality of supports which are made of an insulating material in a flat plate shape and are perpendicularly erected on the top surface of the horizontal base plate 448.

Both ends of the resonance coil 432 are electrically grounded, and at least one end of the resonance coil 432 is electrically grounded via an adjustable tap 462 so that the electrical length of the resonance coil 432 can be finely adjusted when the ashing apparatus 10 is initially installed or process conditions are changed. In FIG. 4, reference numeral 464 denotes a fixed ground at the other side. Furthermore, a power feed unit configured with an adjustable tap 466 is disposed between the grounded ends of the resonance coil 432 for finely adjusting the impedance of the resonance coil 432 when the ashing apparatus 10 is initially installed or process conditions are changed.

That is, the resonance coil 432 includes grounding parts at both ends for electric grounding, and the power feed unit between the grounding parts for receiving power from the high-frequency power supply 444. In addition, at least one of the grounding parts of the resonance coil 432 is position-adjustable, and the power feed unit of the resonance coil 432 is position-adjustable. Since the resonance coil 432 includes the variable grounding part and the variable power feed unit, the resonance frequency and load impedance of the plasma generating chamber 430 can be adjusted more easily as described later.

Optionally, a waveform adjustment circuit configured by a coil and a shield can be inserted in one end or both ends of the resonance coil 432 to allow in-phase and out-of-phase currents to be symmetric with respect to an electric center of the resonance coil 432. The waveform adjustment circuit may be configured as an open circuit by electrically disconnecting the end of the resonance coil 432 or making the end of the resonant coil 432 in an electrically equivalent structure. Alternatively, the end of the resonance coil 432 may be kept in a non-grounded state by a series choke resistor and be series-connected to a fixed reference potential.

The outer shield 452 is installed to prevent leakage of electromagnetic waves from the resonance coil 432 and form capacitance with the resonance coil 432 for constituting a resonant circuit. Generally, the outer shield 452 is made in a cylindrical shape using a conductive material, such as an aluminum alloy, copper, or a copper alloy. For example, the outer shield 452 is spaced about 5 mm to about 150 mm away from the outer circumference of the resonance coil 432. Usually, the outer shield 452 is grounded so that the outer shield 452 can have the same potential as both ends of the resonance coil 432. Optionally, so as to precisely set the resonance frequency of the resonance coil 432, one end or both ends of the outer shield 452 may be configured to be adjustable using a tap, or a trimming condenser may be inserted between the resonance coil 432 and the outer shield 452.

For example, the treatment chamber 445 configured to accommodate a wafer 600 has an approximately short cylindrical shape having a bottom. In the treatment chamber 445, the susceptor table 411, which is configured to support the wafer horizontally and has a short post shape, is installed. At the susceptor table 411, a general electrostatic chuck may be provided.

A proper power supply such as an RF generator capable of supplying power having a desired voltage and frequency to the resonance coil 432 may be used as the high-frequency power supply 444. For example, a high frequency generator capable of supplying about 80 kHz to 800 MHz, 0.5 KW to 5 KW power may be used.

A reflected wave wattmeter 468 is installed at the output side of the high-frequency power supply 444, and information about reflected wave power detected by the reflected wave wattmeter 468 is input to a controller 470 used as a control unit. The controller 470 controls the entire operation of the ashing apparatus 10 as well as the operation of the high-frequency power supply 444. A display 472 is connected to the controller 470 as a display unit. For example, the display 472 displays data detected by various detectors installed in the ashing apparatus 10 such as reflected wave data detected by the reflected wave wattmeter 468. The controller 470 receives information about reflected wave power and controls parts of the ashing apparatus 10 as well.

In the above-described ashing apparatus 10, a wafer 600 is transferred as follows: a wafer 600 is carried to the loadlock chamber 250 (260); the loadlock chamber 250 (260) is evacuated to a vacuum state (vacuum replacement); the wafer 600 is carried from the loadlock chamber 250 (260) to the process chamber 410 (420) through the transfer module 310; photoresist is removed from the wafer 600 in the process chamber 410 (420) (a removing process); and then the wafer 600 is carried back to the loadlock chamber 250 (260) through the transfer module 310.

The removing process is performed in the process chamber 410 (420) so as to remove photoresist, from the wafer 600, which is used as a mask in an ion implantation process prior to a substrate processing process. The photoresist to be removed in the removing process has a two-layer structure composed of an altered layer and a bulk layer, and if the temperature increases to a predetermined level (varying according to the material of the photoresist, for example, about 120° C. to 160° C.), the bulk layer vaporizes such that the altered layer may be ruptured by the pressure of the vaporized bulk layer (a popping phenomenon). For this reason, the photoresist is removed by oxidizing the photoresist using O₂ gas, H₂ gas, N₂ gas, or a mixture thereof while maintaining the wafer 600 at a low temperature.

In detail, the removal of the photoresist (removing process) is performed through a placement process in which a wafer 600 is placed on the lift pins 413 in the process chamber 410 (420), a first removing process performed after the placement process, and a second removing process performed after the first removing process. Hereinafter, the placement process, the first process, and the second process will be described.

The placement process will now be explained. The finger 321 on which a wafer 600 is placed is moved into the treatment chamber 445. At the same time, the lift pins 413 are lifted. The finger 321 places the wafer 600 on the lift pin supporting parts 414 of the lifted lift pins 413. At this time, since the wafer 600 is insulated from the substrate heating unit 463 by a vacuum, the wafer 600 is kept at room temperature (about 25° C.).

The first removing process will now be explained.

After the wafer 600 held at room temperature is placed in the placement process, H₂ gas and O₂ gas are supplied to the plasma generating chamber 430 through the gas supply pipes 455. The H₂ gas may be previously mixed with the O₂ gas or be mixed with the O₂ gas in the plasma generating chamber 430. In the latter case, the gas supply pipes 455 include as many gas supply units as the kinds of gas (in this example, two gas supply units).

After the gas supply, the high-frequency power supply 444 supplies power to the resonance coil 432. Free electrons are accelerated and are collided with gas molecules owing to an induced magnetic field formed inside the resonance coil 432 so that the gas molecules can be excited into plasma.

In this way, the supplied H₂ gas and O₂ gas are excited into plasma.

In the current embodiment, the plasma excitation is performed after the gas is supplied; however, the present invention is not limited thereto. For example, before the gas is supplied, the high-frequency power supply 444 can supply power to the resonance coil 432 to form a magnetic field previously.

While the plasma is generated, the substrate heating unit 463 heats the wafer 600 gradually up to 200° C. If the wafer 600 is rapidly heated, a popping phenomenon can occur. Thus, until surface photoresist is removed to a certain degree, the temperature of the wafer 600 is gradually increased.

Organic components of the photoresist are mainly removed by the gas excited into plasma. As a reaction gas for the first removing process, a mixture of O₂ gas and H₂ is used.

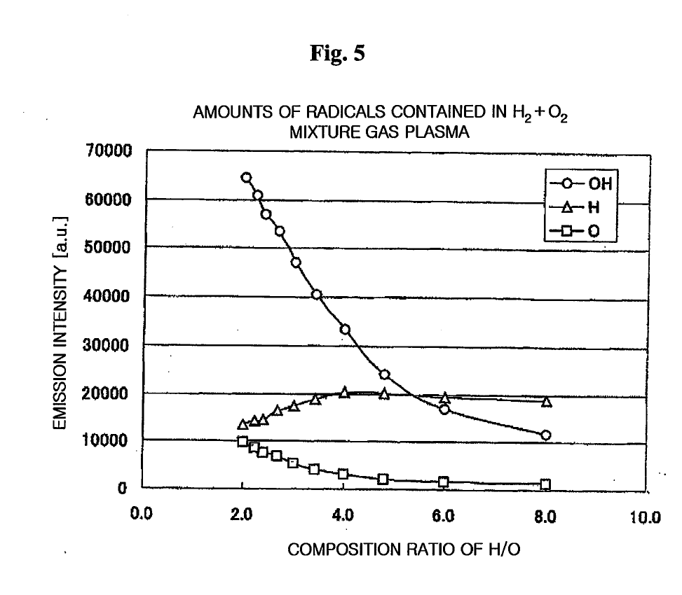

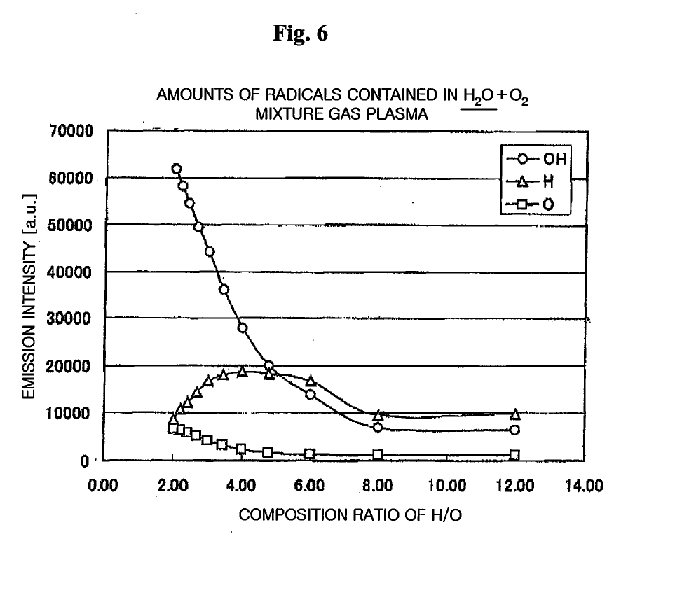

An explanation will be given on the amount of radicals in plasma with reference to FIG. 5 and FIG. 7.

FIG. 5 shows the amounts of OH, H, and O radicals in (H₂+O₂) mixture gas plasma. The vertical axis denotes emission intensity proportional to the amounts of radicals. The horizontal axis denotes a hydrogen/oxygen (H/O) ratio representing the amount of H₂ in the (H₂+O₂) mixture gas.

FIG. 7 shows the amounts of residues after an ashing process.

As shown in FIG. 5, an activate species mainly composed of OH radicals is included in plasma generated by exciting a reaction gas composed of oxygen and hydrogen through an electric discharge. Organic components and impurities included in a hardened layer are efficiently removed through reduction reactions with the OH radicals.

When the H/O ratio is lower than 3, the amount of oxygen (O) radicals of the plasma increases as shown in FIG. 5. If the amount of oxygen (O) radicals increases, dopants of the hardened layer become a nonvolatile oxide by an oxidation reaction, and thus the hardened layer may not be easily removed. Therefore, a popping phenomenon may occur easily, and the dopant oxide may be segregated to form hard residues as shown in FIG. 7, which decreases stripping efficiency in the ashing process. Thus, in the current embodiment, the H/O ratio is kept equal to or higher than 3.

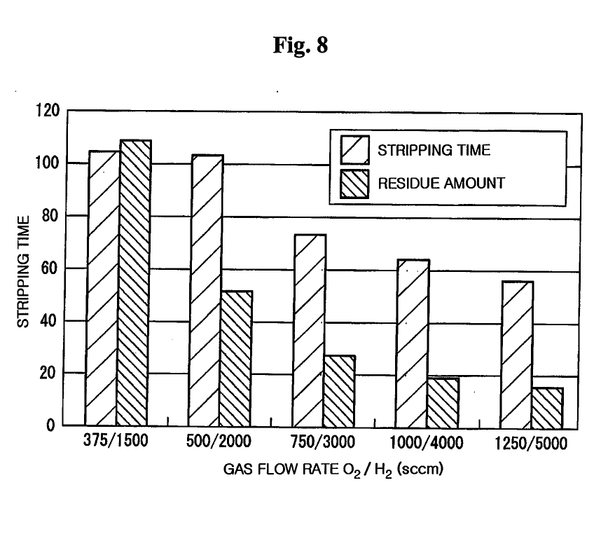

Next, a relationship among the total amount of a reaction gas, stripping (photoresist removing) time, and the amount of residues will be explained with reference to FIG. 8. In FIG. 8, the vertical axis denotes stripping time, and the horizontal axis denotes the flow rates of gases. In detail, the horizontal axis denotes O₂ gas flow rate/H₂ gas flow rate. For example, when the O₂ gas flow rate/H₂ gas flow rate is 375/1500, the flow rate of O₂ gas is 375 sccm, the flow rate of H₂ gas is 1500 sccm, and the total gas flow rate is 1875 sccm.

As shown in FIG. 8, when the total flow rate of a reaction gas is low, a small amount of radicals is supplied, and thus photoresist removing speed reduces. As a result, ashing time increases. Moreover, the amount of residues increases.

Thus, the total flow rate has to be kept equal to or larger than at least 1000 sccm.

On the other hand, if the flow rate of a reaction gas is excessively high, the efficiency of exciting the reaction gas decreases, and the concentration of radicals becomes low, thereby decreasing the photoresist removing speed. Therefore, the amount of radical supply may not be too small and the concentration of radicals may not be too small when the total flow rate of the reaction gas is kept in the range from 1000 sccm to 20000 sccm. Thus, in the current embodiment, O₂ gas is supplied at a rate equal to or higher than 250 sccm, H₂ gas is supplied at a rate equal to or higher than 750 sccm to keep the total flow rate of the reaction gases at a rate equal to or higher than 1000 sccm but not higher than 20000 sccm.

By controlling the total flow rate of the reaction gas in this way, photoresist can be efficiently removed from the wafer 600 although the diameter of the wafer 600 is equal to or greater than 300 mm.

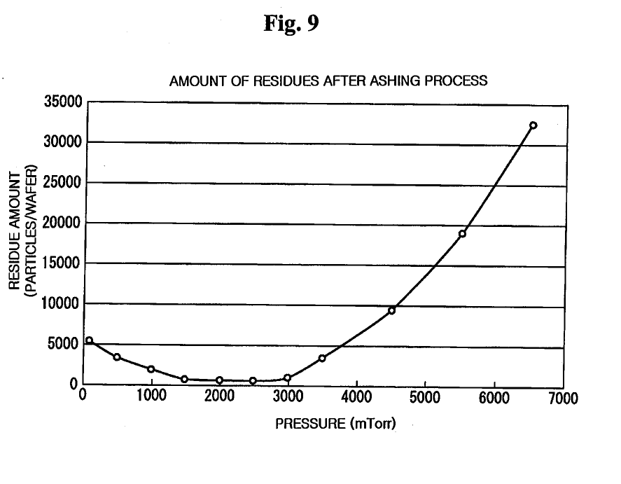

FIG. 9 is a graph providing information about the amount of residues remaining after an ashing process with respect to the process pressure of the ashing process by showing the number of 1-μm or larger particles remaining on the surface of a 300-mm wafer. The process pressure is kept in the range from 100 mTorr to 5500 mTorr. If the process pressure is greater than 5500 mTorr, the number of residues becomes about 20000 particles/wafer which is greater than a regulated number.

More preferably, the process pressure may be kept equal to or lower than 500 mTorr. In this case, the number of particles can be reduced, and at the same time, the ashing rate can be increased. It is even more preferable that the process pressure be equal to or higher than 1500 mTorr but not higher than 3000 mTorr. In this case, the number of particles can be further reduced, and thus a clean process is possible.

If the process pressure is lower than 100 mTorr or higher than 5500 mTorr, problems, such as an increase in the number of particles, an unstable generation of plasma, and a decrease in the ashing rate, can occur easily.

In the current embodiment, O₂ gas and H₂ gas are used as process gases in the first removing process; however, instead of using O₂ and H₂ gases, a mixture of H₂O gas and O₂ gas may be used. In addition, a mixture of NH₃ gas and O₂ gas may alternatively be used.

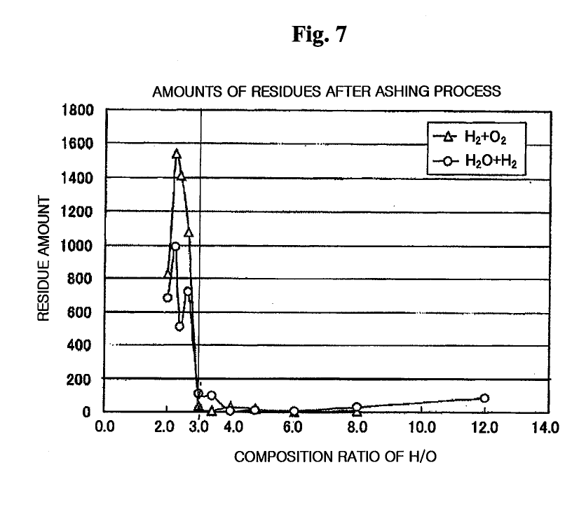

FIG. 6 shows the amount of radicals in the case where a mixture of H₂O gas and O₂ gas is used. Like the vertical and horizontal axes of FIG. 5, the vertical axis of FIG. 6 denotes emission intensity, and the horizontal axis of FIG. 6 denotes the composition ratio of hydrogen/oxygen.

Like in the case of using (H₂+O₂) mixture gas, when the H/O ratio of the (H₂O+O₂) mixture gas is lower than 3, the amount of OH radicals increases; however, the amount of oxygen (O) radicals also increases. In this case, dopants of a hardened layer may become a nonvolatile oxide by an oxidation reaction, and thus the hardened layer may not be easily removed.

Therefore, when the (H₂O+O₂) mixture gas is used, it is also preferable that the H/O ratio of the (H₂O+O₂) mixture gas be kept equal to or higher than 3.

A process gas that can be used in the first removing process may be a mixture gas of O₂ gas and H₂ gas; a mixture gas of H₂O gas and O₂ gas; or a mixture gas of NH₃ and O₂ gas, which is diluted with at least one selected from the group consisting of N₂ gas, He gas, Ne gas, Ar gas, Kr gas, and Xe gas.

Alternatively, a mixture gas prepared by mixing H₂ gas, H₂O gas, NH₃ gas, and O₂ with at least one selected from the group consisting of N₂ gas, He gas, Ne gas, Ar gas, Kr gas, and Xe gas may be used as a process gas of the first removing process.

In the first removing process, O₂ gas is mainly used for removing photoresist, and H₂ gas is used to suppress popping. That is, in the first removing process, owing to an active species (mainly composed of O radicals) obtained from a reaction gas through a high-frequency discharge, organic components of the photoresist can become volatile substances such as CO and CO₂ through reactions with oxygen, and thus the organic components can be discharged in a gas state. As described above, photoresist can be rapidly removed, and the amount of residues can be low by maintaining the H/O ratio equal to or higher than 3.

In the first removing process, the organic components of the photoresist are removed; however, dopants of the photoresist such as phosphorus (P), arsenic (As), and boron (B) are not removed although the dopants combine with O₂ because the dopants are not vaporized due to high bonding strength between the dopants and O₂. That is, in the first removing process, implanted dopants of the photoresist, and oxides of the dopants are not removed from the wafer 600; instead, they are segregated to the surface of the wafer 600.

Next, the second removing process will be explained.

The second removing process is performed to remove dopants segregated to the surface of the wafer 600 by using the reducing characteristics of hydrogen (H).

A reaction gas used in the second removing process has zero percent of O₂ and is supplied with an O₂ gas:N₂ gas:H₂ gas flow ratio of 0:1000:40. The process pressure of the second removing process is lower than the first removing process. For example, the process pressure of the second removing process is 1.5 Torr.

In the second removing process, H₂ gas is used to remove resides, and N₂ gas is used to dilute the H₂ gas.

O₂ gas supplied in the first removing process is interrupted by the flow rate control unit, and only N₂H₂ gas is supplied to the plasma generating chamber 430 through the gas supply pipes 455 in a state where supply of O₂ gas is stopped.

At the same time, the lift pins 413 are moved down. The wafer 600 is moved close to the substrate heating unit 463 to heat the wafer 600. For example, the wafer is heated to 250° C. In the second removing process, the reaction gas (mixture gas) is ionized through a high-frequency discharge to obtain an active species mainly composed of hydrogen (H) radicals so that the dopants segregated to the surface of the wafer 600 can be changed into volatile substances such as PH₃, AsH₃, and B₂H₆ by the active species and be exhausted in a gas state.

O₂ gas can be included in the reaction gas of the second removing process. For example, O₂ gas used in the first removing process can remain in the plasma generating chamber 430 and mixed with N₂H₂ gas supplied in the second removing process.

In this case, the amount of H radicals is reduced by oxidation, or the reaction between the H radicals and the dopants is hindered, such that the segregated dopants are not effectively removed. Therefore, the fraction of O₂ gas in the reaction gas should be 10% or less because the dopants are removed more easily as the fraction of O₂ gas decreases. That is, as the fraction of O₂ gas decreases, residues are removed at a higher rate through reduction reactions by hydrogen (H) radicals.

In the case where plasma is generated using only H₂ gas and N₂ gas, Na is generated due to the reaction vessel 431 made of quartz; however, the generation of Na can be suppressed using O₂ gas. Therefore, to reduce Na contamination, a certain amount of oxygen is added.

For this reason, in the second removing process, instead of interrupting supply of O₂ gas, the supply of O₂ gas may be controlled by the flow rate control unit so that the fraction of O₂ gas in the reaction gas is 10% or less.

If the reaction vessel 431 made of quartz has good-quality, generation of Na is suppressed, and thus O₂ gas is unnecessary.

When the quality of the reaction vessel 431 is considered as described above, it is preferable that the flow rate of O₂ gas be in the range of 0% to 10% of the total flow rate to maintain the residue stripping efficiency at an acceptable level while reducing Na contamination. NH₃ gas may be used instead of using H₂ gas, and inert gas such as He and Ar may be used instead of N₂ gas.

In the first and second removing processes, gas flow rate, gas mixing ratio, and gas pressure are changed. Thus, the load impedance of the high-frequency power supply 444 are changed; however, owing to the frequency matching device 446, the oscillating frequency of the high-frequency power supply 444 can be adjusted according to variations of process temperature or pressure.

Furthermore, in the above-described ashing apparatus 10, when the oscillating frequency of the spiral resonator configured by the resonance coil 432 and the outer shield 452 is varied, the frequency matching device 446 controls the spiral resonator to minimize reflected wave power.

In more detail, the following operations are performed.

When plasma is generated in the first removing process, the oscillating frequency of the high-frequency power supply 444 converges to the resonance frequency of the resonance coil 432. For this, the reflected wave wattmeter 468 detects waves reflected from the resonance coil 432 and sends the level of the reflected waves to the frequency matching device 446.

The frequency matching device 446 adjusts the oscillating frequency of the high-frequency power supply 444 to minimize the reflected waves (reflected wave power). Preferably, the oscillating frequency of the high-frequency power supply 444 can be previously set through an experiment. In this case, such data (for example, data providing information about an oscillating frequency at which a reflected wave level is minimized) are stored in the controller 470, and the oscillating frequency of the high-frequency power supply 444 that converges to the resonance frequency of the resonance coil 432 is determined by comparing a detected reflected wave level with the stored data and considering other factors such as errors of the data.

Although it is ideal that controlling be performed on all devices to minimize reflected waves, use of a common control method for the plurality of deices can be considered. That is, a control method using common software can be considered. In this case, since an oscillating frequency for minimizing reflected waves can be varied according to the devices, oscillating frequencies at which reflected wave levels of the devices are minimized may be previously averaged, and control may be performed for convergence to the average value.

In the second removing process, the flow rate control unit operates to interrupt supply of O₂ gas or maintain the flow rate of O₂ gas equal to or lower than 10% of the total flow rate of supply gas, and supply of power from the high-frequency power supply 444 is continued from the first removing process to maintain electric discharge conditions.

At this time, the gas flow rate, gas mixture ratio, and pressure of the treatment chamber 445 can be varied as compared with those of treatment chamber 445 in the first removing process. In this case, ionization characteristics of gas molecules vary largely, and thus the resonance frequency of the resonance coil 432 varies such that the intensity of reflected waves increases temporarily. Waves reflected from the resonance coil 432 is detected by the reflected wave wattmeter 468, and the reflected wave wattmeter 468 sends the level of the reflected waves to the frequency matching device 446.

The frequency matching device 446 adjusts the oscillating frequency of the high-frequency power supply 444 to minimize the reflected waves (reflected wave power). Preferably, the oscillating frequency of the high-frequency power supply 444 can be previously set through an experiment. In this case, such data (for example, data providing information about an oscillating frequency at which a reflected wave level is minimized) are stored in the controller 470, and the oscillating frequency of the high-frequency power supply 444 that converges to the resonance frequency of the resonance coil 432 is determined by comparing a detected reflected wave level with the stored data and considering other factors such as errors of the data.

Here, instead of setting the oscillating frequency of the high-frequency power supply 444 to different values suitable for minimizing reflected wave levels of a plurality of devices, the average value of the suitable values can be set as the oscillating frequency of the high-frequency power supply 444, as explained in the above description of the first removing process.

Owing to the above-described continuous controlling by the controller, the first and second removing processes can be continuously performed without a plasma loss and re-ignition.

Next, an ashing apparatus, which does not include a frequency matching device 446 and a reflected wave wattmeter 468, will be explained as a comparison example of the ashing apparatus of the preferred embodiment of the present invention. The comparison example has the same structure as the ashing apparatus of the preferred embodiment of the present invention except that the comparison example does not include a frequency matching device 446 and a reflected wave wattmeter 468.

In a first removing process, photoresist is removed. Thereafter, supply of power from a high-frequency power supply 444 is temporarily interrupted. Then, the pressure and gas flow rate of a treatment chamber 445 are reset by controlling a flow rate control unit and a pressure control unit. In a second removing process, N₂H₂ is supplied to a plasma generating chamber 430 to remove residues.

That is, when the procedure goes from the first removing process to the second removing process, electric discharge is stopped, and thus re-ignition is necessary for the second removing process. As a result, a re-ignition time is necessary.

In other words, by using the frequency matching device 446 and the reflected wave wattmeter 468 according to the preferred embodiment of the present invention, time losses such as re-ignition time can be prevented, and the throughput can be improved.

In the above-described embodiment, the removing process is performed twice. When photoresist is removed through a plurality of processes, it is preferable that gas having a H/O ratio of 3 or higher be used as a reaction gas for the first process. If gas having a H/O ratio of 3 or higher is used as a reaction gas for the second process or the next processes, popping may occur to result in residues.

Therefore, gas having a H/O ratio of 3 or higher is used as a reaction gas in the first process for suppressing a popping phenomenon, and photoresist is removed in the next removing processes. In the second process and the next processes, use of gas having a H/O ratio of 3/1 or higher is unnecessary, that is, ashing can be performed using oxygen and hydrogen moderately.

As explained above, according to an aspect of the present invention, there is provided a method of manufacturing a semiconductor device, which includes a process of removing photoresist from a substrate. The removing process is performed by supplying oxygen gas and hydrogen gas to a reaction vessel at a flow rate equal to or higher than 250 sccm and at a flow rate equal to or higher than 750 sccm to keep a hydrogen/oxygen ratio of the oxygen and hydrogen gases equal to or higher than 3, exciting the oxygen gas and the hydrogen gas into plasma in the reaction vessel, and ashing a substrate accommodated in a treatment chamber installed contiguous to the reaction vessel by using the plasma.

According to another aspect of the present invention, there is provided a method of manufacturing a semiconductor device, which includes a process of removing photoresist from a substrate. The removing process includes: a first removing process of removing an organic component from the photoresist of the substrate by exciting a first reaction gas containing at least oxygen and hydrogen molecules into plasma; and a second removing process of removing a dopant precipitate from the substrate by exciting a second reaction gas containing at least hydrogen molecules into plasma after the first removing process is performed, wherein the first reaction gas has a hydrogen/oxygen ratio equal to or higher than 3.

According to another aspect of the present invention, there is provided a substrate processing apparatus including: a reaction vessel configured to be decompressed and excite a reaction gas into plasma; a spiral resonator including a resonance coil wound around the reaction vessel and an outer shield disposed around the resonance coil and electrically grounded; a treatment chamber installed contiguous to the reaction vessel and configured to accommodate a substrate; a power supply configured to supply power to the resonance coil; a reaction gas supply unit configured to supply a reaction gas to the reaction vessel; a flow rate control unit configured to control a flow rate of the reaction gas supplied by the reaction gas supply unit; and a reaction gas supply control unit configured to control the reaction gas supply unit so that when ashing is performed in a plurality of steps, a hydrogen/oxygen ratio of a reaction gas supplied in the first step of the plurality of steps is maintained equal to or higher than 3.

According to the present invention, there is provide a method of manufacturing a semiconductor device and a substrate processing apparatus that are designed to suppress the popping phenomenon and reduce residues remaining on a substrate in a photoresist removing process.

As described above, the present invention may be applied to a semiconductor device manufacturing method including a process of removing photoresist, and a substrate processing apparatus.

While preferred aspects and embodiments of the present invention have been described, the present invention also includes the following embodiments.

(Supplementary Note 1)

According to an embodiment of the present invention, there is provided a method of manufacturing a semiconductor device, the method comprising a process of removing photoresist from a substrate, wherein the removing process is performed by supplying oxygen gas and hydrogen gas to a reaction vessel, exciting the oxygen gas and the hydrogen gas into plasma in the reaction vessel, and ashing a substrate accommodated in a treatment chamber installed contiguous to the reaction vessel by using the plasma, wherein the oxygen gas is supplied at a flow rate equal to or higher than 250 sccm and the hydrogen gas is supplied at a flow rate equal to or higher than 750 sccm, and the supplied oxygen and hydrogen gases have a hydrogen atom/oxygen atom ratio equal to or higher than 3.

(Supplementary Note 2)

According to another embodiment of the present invention, there is provided a method of manufacturing a semiconductor device, the method comprising a process of removing photoresist from a substrate, wherein the removing process is performed by supplying a reaction gas to a reaction vessel, exciting the reaction gas using the reaction vessel, and ashing a substrate accommodated in a treatment chamber installed contiguous to the reaction vessel by using the plasma, wherein the reaction gas has a hydrogen atom/oxygen atom ratio equal to or higher than 3.

(Supplementary Note 3)

In the method of Supplementary Note 2, it is preferable that the reaction gas be prepared by mixing H₂ gas, H₂O gas, NH₃ gas, and O₂ gas with at least one selected from the group consisting of N₂ gas, He gas, Ne gas, Ar gas, Kr gas, and Xe gas.

(Supplementary Note 4)

In the method of Supplementary Note 2, it is preferable that the reaction gas be a mixture of H₂ gas and O₂ gas.

(Supplementary Note 5)

In the method of Supplementary Note 2, it is preferable that the reaction gas be a mixture of H₂O gas and O₂ gas.

(Supplementary Note 6)

In the method of Supplementary Note 2, it is preferable that the reaction gas be a mixture of NH₃ gas and O₂ gas.

(Supplementary Note 7)

In the method of Supplementary Note 4, it is preferable that the reaction gas comprise at least one dilution gas selected from the group consisting of N₂ gas, He gas, Ne gas, Ar gas, Kr gas, and Xe gas.

(Supplementary Note 8)

In the method of Supplementary Note 5, it is preferable that the reaction gas comprise at least one dilution gas selected from the group consisting of N₂ gas, He gas, Ne gas, Ar gas, Kr gas, and Xe gas.

(Supplementary Note 9)

In the method of Supplementary Note 6, it is preferable that the reaction gas comprise at least one dilution gas selected from the group consisting of N₂ gas, He gas, Ne gas, Ar gas, Kr gas, and Xe gas.

(Supplementary Note 10)

According to another embodiment of the present invention, there is provided a method of manufacturing a semiconductor device, the method comprising a process of removing photoresist from a substrate, wherein the removing process comprises: a first removing process of removing an organic component from the photoresist of the substrate by exciting a first reaction gas containing at least oxygen and hydrogen molecules into plasma; and a second removing process of removing a dopant precipitate from the substrate by exciting a second reaction gas containing at least hydrogen molecules into plasma after the first removing process is performed, wherein the first reaction gas has a hydrogen atom/oxygen atom ratio equal to or higher than 3.

(Supplementary Note 11)

According to another embodiment of the present invention, there is provided a substrate processing apparatus comprising: a reaction vessel configured to be decompressed and excite a reaction gas into plasma; a spiral resonator comprising a resonance coil wound around the reaction vessel and an outer shield disposed around the resonance coil and electrically grounded; a treatment chamber installed contiguous to the reaction vessel and configured to accommodate a substrate; a power supply configured to supply power to the resonance coil; a reaction gas supply unit configured to supply a reaction gas to the reaction vessel; a flow rate control unit configured to control a flow rate of the reaction gas supplied by the reaction gas supply unit; and a reaction gas supply control unit configured to control the reaction gas supply unit so that when ashing is performed in a plurality of steps, a hydrogen atom/oxygen atom ratio of a reaction gas supplied in the first step of the plurality of steps is maintained equal to or higher than 3.

(Supplementary Note 12)

It is preferable that the substrate processing apparatus of Supplementary Note 11 further comprise a frequency control unit configured to control an oscillating frequency of the spiral resonator so that a voltage reflected from the spiral resonator is minimized during a transition from the first step to the second step of the plurality of steps.

What is claimed is:

1. A method of manufacturing a semiconductor device, the method comprising a process of removing photoresist from a substrate,
wherein the removing process is performed by supplying oxygen gas and hydrogen gas to a reaction vessel, exciting the oxygen gas and the hydrogen gas into plasma in the reaction vessel, and ashing a substrate accommodated in a treatment chamber installed contiguous to the reaction vessel by using the plasma,
wherein the oxygen gas is supplied at a flow rate equal to or higher than 250 sccm and the hydrogen gas is supplied at a flow rate equal to or higher than 750 sccm, and
the supplied oxygen and hydrogen gases have a hydrogen atom/oxygen atom ratio equal to or higher than 3.

2. A method of manufacturing a semiconductor device, the method comprising a process of removing photoresist from a substrate,
wherein the removing process is performed by supplying a reaction gas to a reaction vessel, exciting the reaction gas using the reaction vessel, and ashing a substrate accommodated in a treatment chamber installed contiguous to the reaction vessel by using the plasma,
wherein the reaction gas has a hydrogen atom/oxygen atom ratio equal to or higher than 3.

3. The method of claim 2, wherein the reaction gas is prepared by mixing H₂ gas, H₂O gas, NH₃ gas, and O₂ gas with at least one selected from the group consisting of N₂ gas, He gas, Ne gas, Ar gas, Kr gas, and Xe gas.

4. The method of claim 2, wherein the reaction gas is a mixture of H₂ gas and O₂ gas.

5. The method of claim 2, wherein the reaction gas is a mixture of H₂O gas and O₂ gas.

6. The method of claim 2, wherein the reaction gas is a mixture of NH₃ gas and O₂ gas.

7. The method of claim 4, wherein the reaction gas comprises at least one dilution gas selected from the group consisting of N₂ gas, He gas, Ne gas, Ar gas, Kr gas, and Xe gas.

8. The method of claim 5, wherein the reaction gas comprises at least one dilution gas selected from the group consisting of N₂ gas, He gas, Ne gas, Ar gas, Kr gas, and Xe gas.

9. The method of claim 6, wherein the reaction gas comprises at least one dilution gas selected from the group consisting of N₂ gas, He gas, Ne gas, Ar gas, Kr gas, and Xe gas.

10. A method of manufacturing a semiconductor device, the method comprising a process of removing photoresist from a substrate, wherein the removing process comprises:
a first removing process of removing an organic component from the photoresist of the substrate by exciting a first reaction gas containing at least oxygen and hydrogen molecules into plasma; and
a second removing process of removing a dopant precipitate from the substrate by exciting a second reaction gas containing at least hydrogen molecules into plasma after the first removing process is performed,
wherein the first reaction gas has a hydrogen atom/oxygen atom ratio equal to or higher than 3.

11. A substrate processing apparatus comprising:
a reaction vessel configured to be decompressed and excite a reaction gas into plasma;
a spiral resonator comprising a resonance coil wound around the reaction vessel and an outer shield disposed around the resonance coil and electrically grounded;
a treatment chamber installed contiguous to the reaction vessel and configured to accommodate a substrate;
a power supply configured to supply power to the resonance coil;
a reaction gas supply unit configured to supply a reaction gas to the reaction vessel;
a flow rate control unit configured to control a flow rate of the reaction gas supplied by the reaction gas supply unit; and
a reaction gas supply control unit configured to control the reaction gas supply unit so that when ashing is performed in a plurality of steps, a hydrogen atom/oxygen atom ratio of a reaction gas supplied in the first step of the plurality of steps is maintained equal to or higher than 3.

12. The substrate processing apparatus of claim 11, further comprising a frequency control unit configured to control an oscillating frequency of the spiral resonator so that a voltage reflected from the spiral resonator is minimized during a transition from the first step to the second step of the plurality of steps.
